(19) United States
(12) Patent Application Publication
(10) Pub. No.: US 2004/0238828 A1
(43) Pub. Date: Dec. 2, 2004

(54) Semiconductor optical integrated device

(75) Inventor: Masashi Ito, Kanagawa (JP)

Correspondence Address: McDERMOTT, WILL & EMERY, 600 13th Street, N.W., Washington, DC, 20005-3096, US

(73) Assignee: SUMITOMO ELECTRIC INDUSTRIES, LTD.

(21) Appl. No.: 10/797,197

(22) Filed: Mar. 11, 2004

(30) Foreign Application Priority Data
Mar. 14, 2003 (JP) 2003-070492

(51) Int. Cl. H01L 27/15; H01L 33/00

(52) U.S. Cl. 257/79; 257/98; 257/94

(57) ABSTRACT

The present invention provides an optical semiconductor integrated device having an anti-reflection coating on the facet with a thinner thickness than those used in a conventional device. The device of the present invention comprises an light-generating region and a light-modulating region having a first facet for outputting light generated in the light-generating region and modulated in said light-modulating region. The first facet provides an anti-reflection coating including a first layer closest to the light-modulating region and a second layer. The first layer has a first refractive index and the second layer has a second refractive index greater than the first refractive index.

### BACKGROUND OF THE INVENTION

1. Field of the Invention

This invention relates to a structure of an optical integrated device and a method for manufacturing the optical integrated device.

2. Related Prior Art

Structures of an anti-reflection coating for a semiconductor optical device, especially for a semiconductor laser and a semiconductor optical amplifier have been disclosed in various documents, for example, Japanese patent laid open H07-066500 and Japanese Journal of Applied Physics, volume 36, pages from L52 to L54, published in 1997.

In the optical integrated device, in which a light-modulating device and a light-generating device such as a semiconductor laser are integrated in single semiconductor substrate, an anti-reflection coating is generally applied to a light-emitting facet to reduce the optical reflectivity thereof. However, when characteristics of the anti-reflection coating do not match the semiconductor body constituting the light-generating device and the light-modulating device, mechanical stress may be induced in the interface between the anti-reflection coating and the semiconductor body, which causes various surface states and optically activated dislocations. Therefore, the anti-reflection coating with a stress free characteristic is widely requested in the field of the optical integrated device. One key solution is to thin the anti-reflection coating.

The anti-reflection coating disclosed in the Japanese patent laid open H07-066550 has a plurality of layers, the embodiment of which includes five layers made of inorganic materials, on the light-emitting facet, thereby thickening the total thickness thereof. Further, the layer closest to the semiconductor body must have a quarter wavelength characteristic, the thickness of which is solely determined by the wavelength of the light generated in the light-generating device. Therefore, the thickness of the layer can not be thinned. On the other hand, multi-layered structure of the anti-reflection coating disclosed in the prior document, Japanese Journal of Applied Physics vol. 36, pp. L52 (1997), has a structure that a layer having relatively large refractive index and another layer having relatively small refractive index are stacked alternately. However, stress due to the anti-reflection coating and the semiconductor body seems to be left out of account.

### SUMMARY OF THE INVENTION

One object of the present invention is to provide an anti-reflection coating having thinner thickness on an optical semiconductor body. According to the present invention, a semiconductor optical integrated device comprises a light-generating region and a light-modulating region having a first facet. The light-generating region generates light with a predetermined wavelength. The light-modulating region modulates light generated in the light-generating region. The light-modulating region also provides a facet for outputting light generated in the light-generating region and modulated in the light-modulating region. According to the present invention, the facet provides a coating, which comprises a first layer closest to the light-modulating region and a second layer. The first layer has a first refractive index and the second layer has a second refractive index greater than the first refractive index. Moreover, the coating shows an anti-reflection characteristic at the predetermined wavelength of the light generated in the light-generating region.

Since the first layer of the anti-reflection coating has the refractive index smaller than that of the second layer, the total thickness of the first layer and the second layer may be thinned, thereby reducing the stress induced between the anti-reflection coating and the semiconductor body.

Another aspect of the present invention is relating to a semiconductor optical amplifier. The semiconductor optical amplifier of the present invention comprises a light-generating region, a first facet and a second facet. The first and second facets sandwich the light-generating region therebetween. The first facet provides an anti-reflection coating including a first layer and a second layer. A refractive index of the first layer is smaller than that of the second layer. Therefore, the total thickness of the first layer and the second layer may be thinned, thereby reducing the stress induced between the anti-reflection coating and the semiconductor body.

### BRIEF DESCRIPTION OF DRAWINGS

FIG. 1 is a perspective view of a semiconductor optical integrated device according to the first embodiment of the present invention;

FIG. 2 is a cross sectional view of the semiconductor integrated device along the line I-I shown in FIG. 1;

FIG. 3 is an expanded view of a facet portion of the semiconductor optical integrated device;

FIG. 4A is a perspective view showing a semiconductor wafer in which an array of device chips is processed, and FIG. 4B shows a device chip processed in the wafer;

FIG. 5A is a perspective view showing the optical waveguide at the manufacturing process, and FIG. 5B shows an appearance of the current blocking layer;

FIG. 6A shows a process for forming ohmic electrodes and FIG. 6B shows an appearance of dicing the semiconductor wafer;

FIG. 7A shows a process for forming the first layer of the anti-reflection coating in an ion-assisted evaporation apparatus, and FIG. 7B is a diagram for forming the second layer on the first layer;

FIG. 8 shows a reflective spectrum of the anti-reflection coating of the present invention;

FIG. 9 shows a current-voltage characteristics of the anti-reflection coating of the present invention; and

FIG. 10 is a cross sectional view of the optical semiconductor device according to the second embodiment of the invention.

### DETAILED DESCRIPTION OF PREFERRED EMBODIMENTS

Next, preferred embodiments of the present invention will be described as referring to accompanying drawings. In the explanation of drawings, same elements will be referred by same symbols or numerals without overlapping description. Dimensions of drawings do not always reflect their explanation for the sake of the convenience.

(First Embodiment)

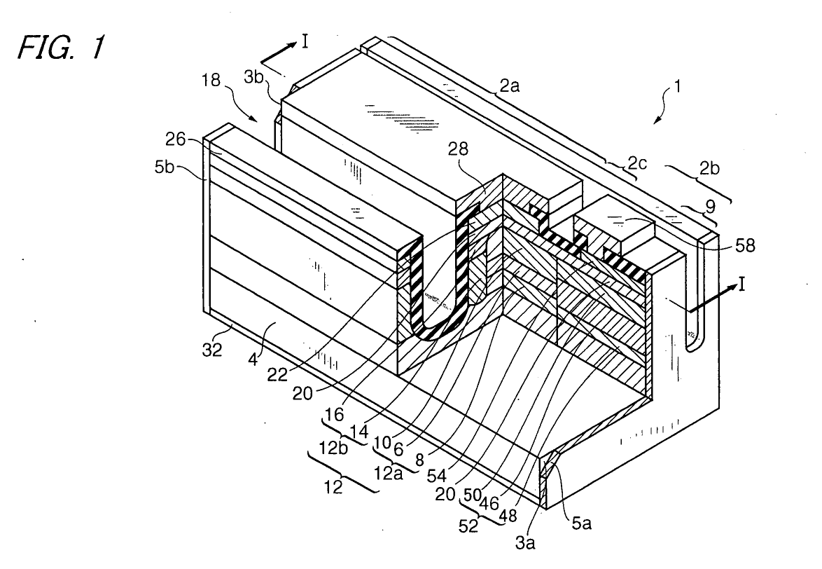

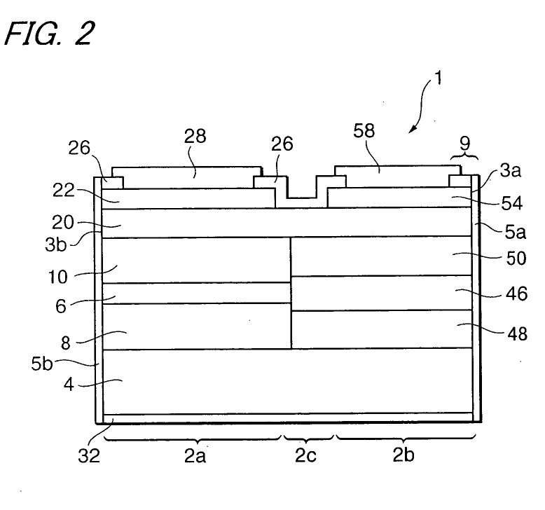

FIG. 1 is a perspective view of an optical integrated device 1 according to the first embodiment. FIG. 2 is a cross sectional view of the optical integrated device 1 along the line I-I in FIG. 1. The optical integrated device 1 includes a light-generating region 2a, a light-modulating region 2b, and first and second facets 3a and 3b. On the first facet 3a, an anti-reflection coating 5a is provided, while a high-reflection coating 5b is provided on the second facet 3b. Between the light-generating region 2a and the light-modulating region 2b, an isolating region 2c is formed. The light-generating region 2a generates light with a predetermined wavelength, and the light-modulating region 2b modulates light generated in the light-generating region 2a. These regions, the light-generating region 2a, the light-modulating region 2b and the isolating region 2c, are formed on a semiconductor substrate such as n-type InP.

The light-generating region 2a has a mesa 12 that includes an active layer 6, an n-type cladding layer 8 and a p-type cladding layer 10. The n-type cladding layer 8 and the p-type cladding layer 10 sandwiches the active layer 6 therebetween. These layers of active layer 6, the n-type cladding layer 8 and the p-type cladding layer 10 are made of group III-V compound semiconductor materials, respectively, and constitutes an optical waveguide 12a.

The mesa 12 includes the optical waveguide 12a and current blocking layers 12b, which includes a semiconductor layer 14 and an n-type semiconductor layer 16 provided on the semiconductor laser 14 in both sides of the optical waveguide 12a. The mesa 12 provides a p-type semiconductor layer 20 on the optical waveguide 12a and each current blocking layers 12b. The mesa further provides a contact layer 22 on the p-type semiconductor layer 20.

The optical integrated device 1 also provides a pair of grooves 18 on the both sides of the mesa 12. The groove 18 reaches the substrate 4 as gouging the semiconductor layers 14, 16, 20 and 22. On the mesa 12a in the light-generating region, an ohmic electrode 28 for the anode is provided with an insulating layer 26 made of inorganic material containing silicon between the electrode 28 and the contact layer 20. The insulating layer 26 has an aperture, through which the electrode 28 is in electrically contact with the contact layer 22. Another ohmic electrode 32 is provided in the whole back surface of the substrate 4, which operates as a cathode electrode.

The light-modulating region 2b also provides a mesa 52 that includes an active layer 46, an n-type cladding layer 48 and a p-type cladding layer 50. The n-type cladding layer 48 and the p-type cladding layer 50 sandwiches the active layer 46 therebetween. These semiconductor layers 46, 48 and 50, which forms a waveguide, are made of group III-V compound semiconductor material, especially in the present embodiment, the composition of these semiconductor layers 46 to 50 are identical with those formed in the light-generating region 2a. The waveguide formed by the semiconductor layer from 46 to 50 optically couples to the waveguide 12a in the mesa 12. The mesa 52 also provides a pair of current blocking layers in both sides thereof, which is not shown in FIG. 1, and provides the p-type semiconductor layer 20 thereon, on which the contact layer 54 is disposed.

The mesa 52 in the light-modulating region 2b provides an ohmic electrode 58, which operates as an anode of the semiconductor optical device 1, and another ohmic electrode 32 in the whole back surface of the substrate 4, which functions as a cathode of the light-modulating region.

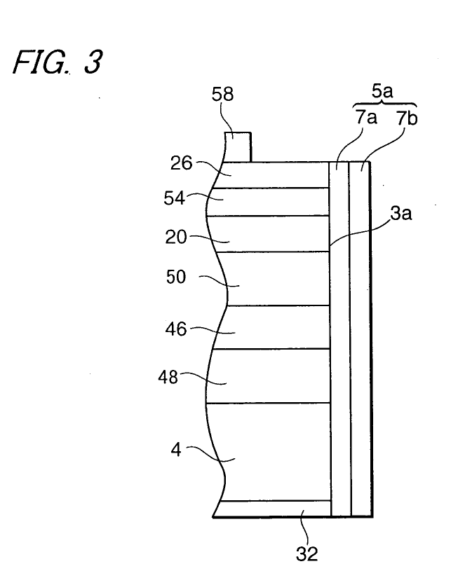

FIG. 3 is a magnified view showing an edge portion 9 of the semiconductor optical device 1. Next, The anti-reflection coating 5a will be described as referring to FIG. 3. The anti-reflection coating 5a shows an extremely low reflectivity, for example 0.1% or less, at a wavelength of the light generated by the light-generating region 2a.

The anti-reflection coating 5a comprises two layers. The first layer 7a is preferably made of, for example, silicon nitride (SiN), silicon oxide (SiO₂), silicon oxi-nitride (SiON) and aluminum oxide (Al₂O₃). The refractive index of these materials is generally smaller than 2 but slightly depends on process parameters such as manufacturing technique itself and types of source materials. The second layer is preferably made of, for example titanium oxide (TiO₂) and tantalum oxide (Ta₂O₅). The refractive index of these materials is generally greater than 2, which also depends on process parameters. The refractive index of these materials partly depends on the manufacturing process, so the reflectivity of the anti-reflection coating 5a can be lowered by adjusting not only the thickness of first and second layers 7a, 7b but also the process thereof.

On the other hand, the reflectivity of the reflective coating 5b provided on the second facet 3b has a significant value, for example between 85% to 95%, as comparing to that of the anti-reflection coating 5a. The reflective coating 5b may made of multi-layered dielectric film.

(Second Embodiment)

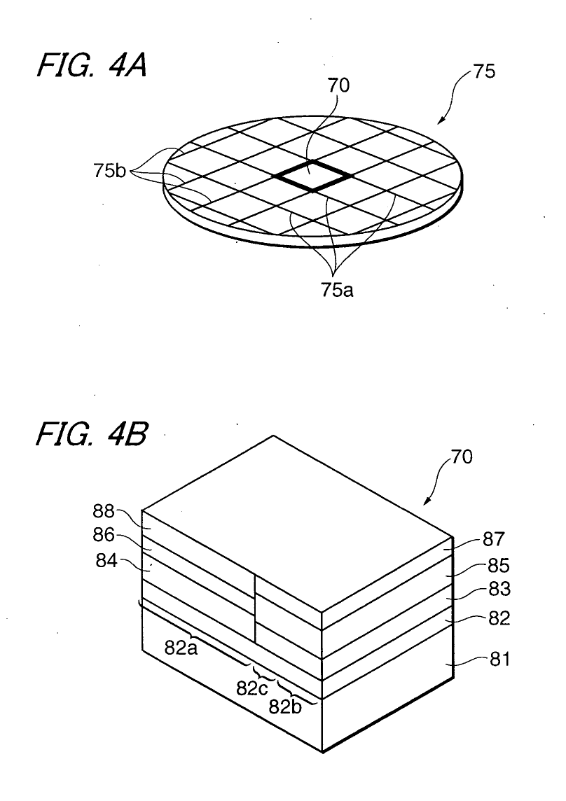

Next, the method of manufacturing the semiconductor optical device 1 will be described as referring to FIG. 4A to FIG. 7B.

FIG. 4A shows a semiconductor wafer, in which the semiconductor optical device 70 is processed, and FIG. 4B shows an individual semiconductor optical device 70. The semiconductor optical device 70 is manufactured by dicing the semiconductor wafer 75 shown in FIG. 4A along predetermined scribe lines 75a and 75b.

Growth of Semiconductor Films

Next, the manufacturing process of the semiconductor optical device 70 shown in FIG. 4B will be described. As shown in FIG. 4B, on the semiconductor substrate 81, which is made of n-type InP, a buffer layer 82 made of n-type InP is formed. The substrate 81 provides a first region 82a, where the light-generating region is to be formed, and a second region 82b, where the light-modulating region is to be formed. On the first region 82a, a series of semiconductor layers of an n-type InP 84, an active layer 86 and a p-type InP 88, is sequentially grown by the Organic Metal Vapor Phase Epitaxy (OMVPE) technique. Same technique grows a series of semiconductor layer of an n-type InP 83, an active layer 85, and a p-type InP 87 on the InP buffer layer 82 in the second region 82b.

Formation of Waveguide Mesa

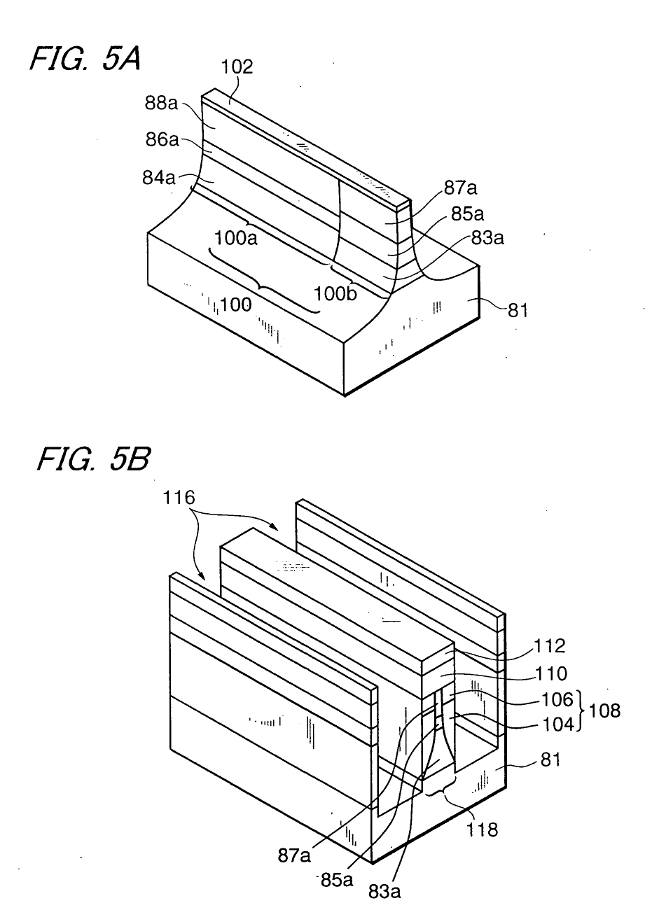

Referring to FIG. 5A, mesas 100a and 100b are formed. A mask layer 102 made of inorganic material containing silicon is formed on the p-type InP 87 and 88 in FIG. 4B to form the mesa 100. Using this mask layer 102, a series of semiconductor layers grown in the first region 82a and the second region 82b are etched to exposure the semiconductor substrate 81. As a results of the etching, the first mesa 100a includes the n-type cladding layer 84a, the active layer 86a and the p-type cladding layer 88a in the first region 82a, while the second mesa 100b includes the n-type cladding layer 83a, the active layer 85a, and the p-type cladding layer 87a in the second region 82b.

Formation of the Current Blocking Layer

As shown in FIG. 5B, a current blocking layer 108 including an InP with a high-resistivity and an n-type InP is formed so as to surround first and second mesas 100a and 100b by the OMVPE technique. The high-resistive InP layer may be doped with Fe. On the current blocking layer 108, a p-type InP layer 110 and a p-type GaInAs layer 112 are formed. The p-type GaInAs layer is to be converted in to the contact layer for first and second regions 82a and 82b. A groove 116 forms a mesa 118 that includes two mesas 100a and 100b, the current blocking layer 108, the p-type InP layer 110 and the contact layer 112.

Formation of Ohmic Electrodes

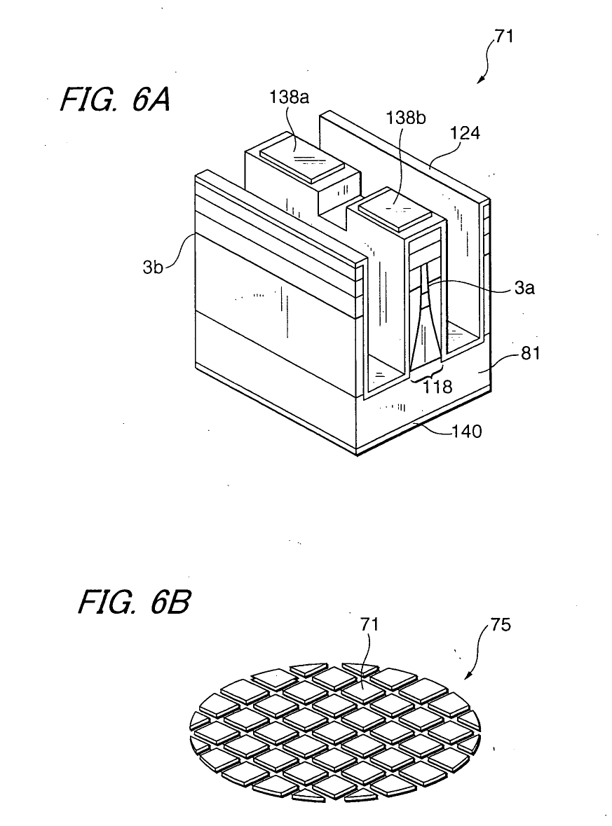

FIG. 6A shows the contact layer after etching the isolating region 2c thereof. According to this etching, the contact layer is divided into two portions, one is for the light-generating region 2a and the other is for the light-modulating region 2b. Subsequently to the etching of the contact layer, an inorganic film 124 containing silicon is formed on the respective contact layer. The p-ohmic electrodes 138a and 138b are deposited on to the contact layer and the inorganic film 124 after forming apertures to expose the surface of the contact layer of respective region 2a and 2b. The n-ohmic electrode 140 is formed onto the whole back surface of the substrate 81.

Cleavage of the Semiconductor Wafer

As shown in FIG. 6B, cleaving the wafer 75 separates individual semiconductor optical devices into device chips 71, which exposes first and second facets 3a and 3b of the device chip 71. Namely, cleavage planes of the wafer 75 function as the facet of the device chip 71. The cross section of the device chip 71 reveals semiconductor layers grown in series, and this cross section becomes a light-emitting surface of the device chip 71.

Formation of Anti-Reflection Coating

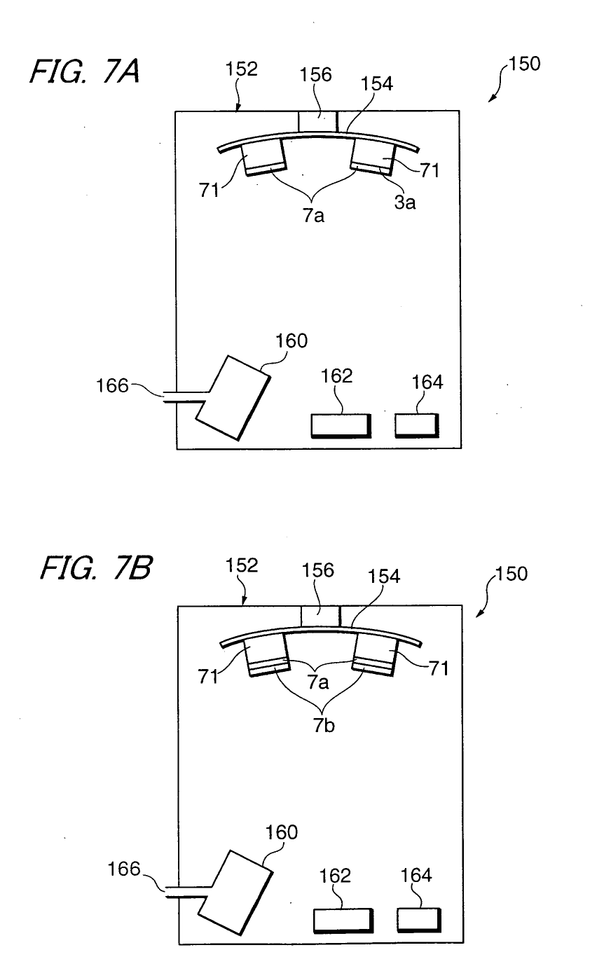

The anti-reflection coating is formed by the ion-assisted evaporation technique on the first facet 3a revealed by the cleavage of the wafer. FIG. 7A is a diagram showing the ion-assisted evaporation technique to form the first film 7a of the anti-reflection coating. The apparatus 150 for the ion-assisted evaporation technique includes a voltage source for accelerating ions and another voltage source for accelerating electrons, both are not shown in FIG. 7A. The apparatus 150 has a mechanism 154 for holding the device chip 71 and a rotor 156 for rotating the mechanism 154 in the upper portion thereof. The apparatus 150 also has an ion gun 160, an electron gun 162 and a source 164 in the lower portion thereof. The ion gun 160 and the electron gun 162 face to the first facet 3a of the device chip 71.

The ion gun 160 ionizes atoms containing in the source gas supplied from the inlet 166 by introducing atoms within the electric field formed by the voltage source and accelerates thus ionized ions. The electron gun 162 irradiates the source with electron beams generated by the high-voltage source. Sources thus evaporated by the electron gun head toward the device chip 71.

The process for forming the anti-reflection coating is that the device chip is set to the holding mechanism 154 in the first step. A cartridge filled with aluminum oxide, as a source material 164 for the first layer 7a, is set within the apparatus 150. A mixed gas of the oxygen and the argon is guided into the ion gun 160 through the inlet 166. The oxygen and argon are ionized within the ion gun and are headed to the device chip 71. On the other hand, by irradiating the aluminum oxide with the electron beam 162, the aluminum oxide may be evaporated and headed to the device chip 71. Thus, on the first facet 3a of the device chip 71 forms an aluminum oxide film as a first layer 7a of the anti-reflection coating with a thickness of about 130 nm.

FIG. 7B is a diagram showing the formation of the second layer 7b of the anti-reflection coating on the device chip 71. Another source cartridge 164 filled up with titanium oxide is set to the apparatus 150. Similar process to the formation of the first layer 7a deposits the titanium oxide layer 7b on the aluminum oxide layer 7a with a thickness of about 50 nm. The thickness of the aluminum oxide layer 7a and that of the titanium oxide layer 7b are so defined that the reflectivity of the anti-reflection coating becomes nearly 0% at the wavelength of 1,550 nm at which the light-generating region 2a emits light. Thus formed anti-reflection coating comprises two layers, hereinafter denoted as structure A, of the aluminum oxide with the thickness of 130 nm and the titanium oxide with to thickness of 50 nm, the total thickness of the anti-reflection coating 5a becomes 180 nm.

Investigating the relation between the thickness of layers and the wavelength, the thickness of the first layer 7a and that of the second layer 7b are not necessary to satisfy the relation of the half-wavelength or the quarter-wavelength, where the wavelength indicates that the light-generating region generates light. In the embodiment previously described, the thickness of the first layer 7a is about 130 nm and that of the second layer 7b is about 50 nm, each thickness is smaller than the quarter-wavelength. Moreover, the latter thickness is thinner than the former. The reflective-coating may be processed by the similar method to that for the anti-reflection coating. However, another know techniques, such as plasma-enhanced chemical vapor deposition, may be applicable for the formation of the reflective-coating.

Next, the anti-reflection coating A thus processed will be compared to a conventional anti-reflection coating B disclosed in Japanese Journal of Applied Physics, volume 36, page L52 to L54, published in 1997. The conventional coating B has two layers of titanium oxide and aluminum oxide on the first facet 3b of the device chip 71, which are formed by the ion-assisted evaporation technique. The thickness of the first layer 7a, titanium oxide layer, is about 100 nm and that of the second layer 7b, aluminum oxide layer, is formed on the titanium oxide layer with a thickness of 185 nm. The thickness of the first layer 7a and that of the second layer 7b are determined such that the reflectivity thereof becomes nearly 0% at 1,550 nm. Clearly, the total thickness of the structure A is thinner than that of the structure B.

Further, stress to the semiconductor optical device by these anti-reflection coatings A and B is investigated. The stress of the coatings was evaluated by the warp of the wafer on which respective coatings are formed. The structure A indicated the stress of −361.5 MPa, while the structure B indicated −609.3 MPa. Therefore, the structure A has smaller stress compared to the conventional structure B. The reason why the structure A has smaller stress may be considered that the total thickness of the structure A is thinner than that of the structure B.

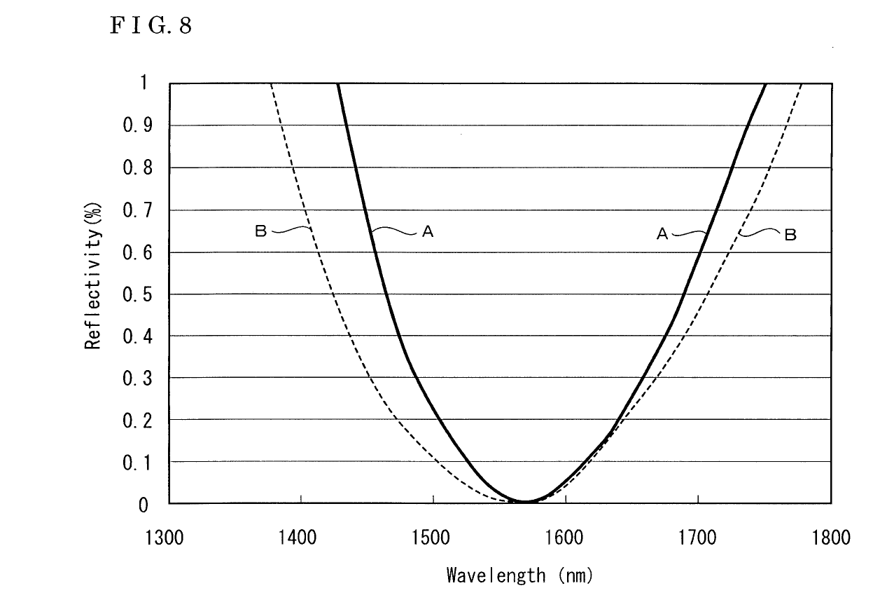

The reflectivity of both structures was investigated. FIG. 8 is a spectrum showing the practically measured reflectivity of respective structures A and B. From FIG. 8, even the anti-reflection coating having the structure A shows the minimum reflectivity below 0.1% and the width of the wavelength where the reflectivity becomes below 0.1% is approximately 80 nm, which is enough wide for the practical application.

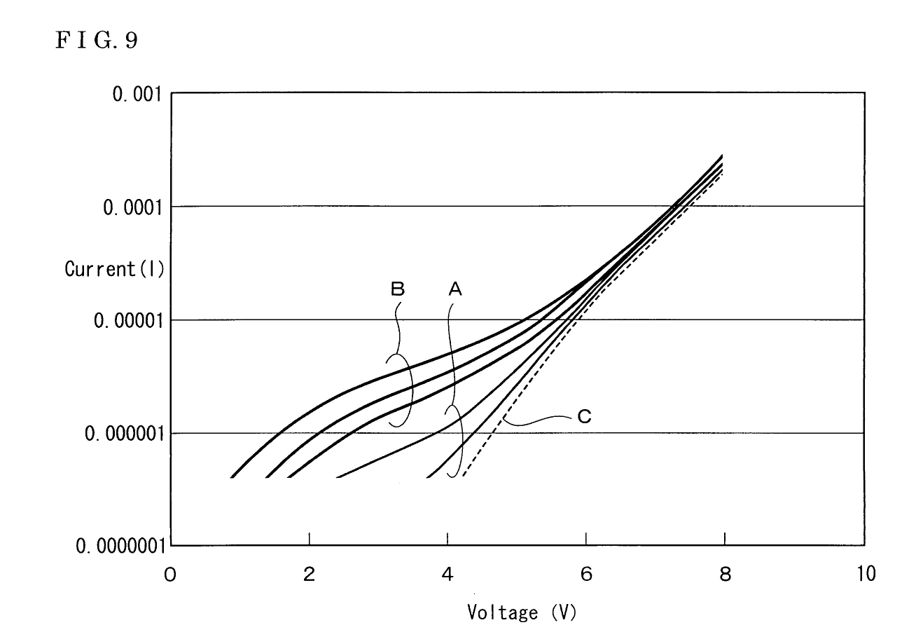

Next, the leak current of the semiconductor optical device 1 having the anti-reflection coating 5a on the first face 3a was investigated. FIG. 9 is a current-voltage characteristic of the device 1. In FIG. 9, symbol A denotes the results for the structure A, symbol C denotes the results for the conventional structure B, and symbol C is a result when no anti-reflection coating is provided.

From FIG. 9, the anti-reflection coating having the structure A generates less leak current as compared to the structure B. The anti-reflection coating 5a of the structure A has the first layer 7a having the refractive index thereof smaller than that of the second layer 7b. On the other hand, the conventional anti-reflection coating has the first layer made of titanium oxide, the refractive index of which is greater than that of the second layer. Since the titanium ions have high energy, when accelerated by the ion gun 162, the energy is released as the titanium oxide attaches to the first facet 3a, which brings mechanical and chemical damages on the facet 3a. These damages generates recombination centers and various surface states between the energy band of the semiconductor material, which induces the leak current. Therefore, the conventional structure B shows greater leak current than the structure A according to the present invention.

Various types of combination of the material for the first layer 7a and the second layer 7b except the combination of the structure A were investigated. Combinations under investigated are shown in Table for the wavelength of 1,550 nm and 1,300 nm.

TABLE

| wavelength | Combination | | Thickness (nm) | |
|---|---|---|---|---|
| (nm) | (1st/2nd) | First | Second | Total |
| 1550 | Al₂O₃/TiO₂ | 130 | 50 | 180 |
| | SiO₂/TiO₂ | 117 | 59 | 176 |
| | TiO₂/Al₂O₃ | 100 | 185 | 285 |
| | TiO₂/SiO₂ | 123 | 196 | 319 |
| 1300 | Al₂O₃/TiO₂ | 100 | 40 | 150 |
| | SiO₂/TiO₂ | 95 | 51 | 146 |
| | TiO₂/Al₂O₃ | 80 | 150 | 230 |
| | TiO₂/SiO₂ | 102 | 168 | 270 |

As listed in Table 1, when the material of the second layer 7b is so selected that the refractive index thereof is greater than that of the first layer 7a, the total thickness of the anti-reflection coating 5a may be thinner than the conventional coating.

(Third Embodiment)

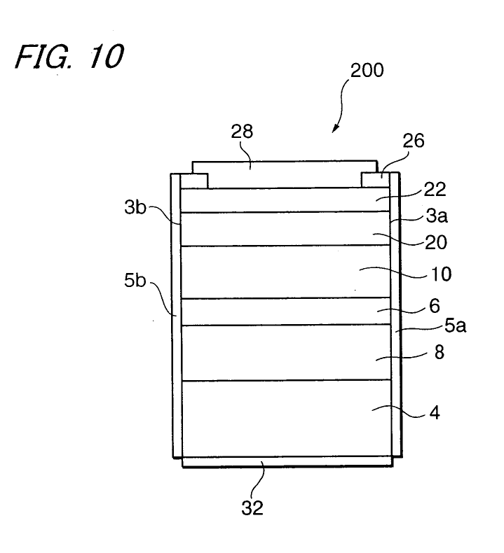

FIG. 10 is a cross sectional view showing a semiconductor amplifier 200. The semiconductor amplifier 200 has a similar structure to that of the optical integrated device according to the first embodiment. The semiconductor optical amplifier 200 comprises a semiconductor substrate 4, an n-type semiconductor layer 8, an active layer 6, a p-type semiconductor layer 10, a first facet 3a and a second facet 3b. These layers from 6 to 10 are grown on the substrate 4. The active layer 6, the n-type layer 8 and the p-type layer 10 constitute a mesa, which is an optical waveguide and is not shown in FIG. 10. The first facet 3a has an anti-reflection coating 5a, while the second facet 3b thereof has a high-reflection coating 5b. The semiconductor material of these layers 6, 8, and 10, and their compositions are same as those in the first embodiment.

The semiconductor optical amplifier 200 may generate light with an inherent wavelength such as 1,550 nm. On the waveguide, a p-type semiconductor layer 20 is provided, and a contact layer 22 is provided on the p-type semiconductor layer 20. An ohmic electrode 28 is disposed on the contact layer for an anode electrode. Between the ohmic electrode 28 and the contact layer 22, an inorganic insulating layer 26 containing silicon is provided. On the back surface of the substrate 4, another ohmic electrode 32 for the cathode is deposited. The optical semiconductor amplifier 200 may be manufactured by a similar process for the optical integrated device previously described.

From the invention thus described based on preferred embodiments, it will be obvious that the invention and its application may be varied in many ways.

For example, although the optical integrated device and the semiconductor optical amplifier are described as embodiments, the anti-reflection coating of the present invention may be applicable to another device such as a distributed feedback laser (DFB laser), an optical modulator and a distributed Bragg reflector laser (DBR laser). Although the wavelength of the light generated by the device is only described for the case of 1,550 nm and 1,300 nm, the present invention may be also applicable to other wavelengths.

Moreover, another configuration may realize nearly 0% reflectivity at 1,550 nm and be applicable as the anti-reflection coating. Namely the anti-reflection coating 5a is a combination of a silicon oxide (SiO₂), which has a thickness of 133 nm and a refractive index of about 1.45, for the first layer 7a closest to the semiconductor body, and an amorphous silicon (a-Si), which has a thickness of 21 nm and a refractive index of about 3.5 for the second layer 7b. The titanium oxide (TiO₂) or the tantalum oxide (Ta₂O₅) are superior to the amorphous silicon in the viewpoint of the resistivity, namely the leak current between the n-type semiconductor layer and the p-type semiconductor layer sandwiching the active layer therebetween. Therefor, when the SiO₂ is applied for the first layer 7a of the anti-reflection coating 5a, the titanium oxide and the tantalum oxide may be preferable for the second layer 7b.

What is claimed is:

1. An semiconductor optical integrated device, comprising:
a light-generating region for generating light with a predetermined wavelength; and
a light-modulating region having a first facet for outputting light generated in said light-generating region and modulated in said light-modulating region,
wherein said first facet provides a coating including a first layer closest to said light-modulating region and a second layer, said first layer having a first refractive index and said second layer having a second refractive index greater than said first refractive index, and
wherein said coating shows an anti-reflection characteristic at said predetermined wavelength.

2. The semiconductor optical integrated device according to claim 1, wherein said first layer is made of a material selected from a group of silicon nitride, silicon oxide, silicon oxi-nitride and aluminum oxide.

3. The semiconductor optical integrated device according to claim 2, wherein said second layer is made of a material selected from a group of titanium oxide and tantalum oxide.

4. The semiconductor optical integrated device according to claim 1, wherein said second layer is made of a material selected from a group of titanium oxide and tantalum oxide.

5. The semiconductor optical integrated device according to claim 1, wherein said light-generating region and said light-modulating region further comprise an InP substrate, an n-type InP layer provided on said InP substrate, an active layer provided on said n-type InP layer, and a p-type InP layer provided on said active layer.

6. An semiconductor optical device, comprising:
a light-generating region for generating light with a predetermined wavelength;
a first facet; and
a second facet, said first facet and said second facet sandwiching said light-generating region therebetween,
wherein said first facet provides a coating including a first layer closest to said light-generating region and a second layer, said first layer having a first refractive index and said second layer having a second refractive index greater than said first refractive index, and
wherein said coating shows an anti-reflection characteristic at said predetermined wavelength.

7. The semiconductor optical device according to claim 6, wherein said first layer is made of a material selected from a group of silicon nitride, silicon oxide, silicon oxi-nitride and aluminum oxide.

8. The semiconductor optical device according to claim 7, wherein said second layer is made of a material selected from a group of titanium oxide and tantalum oxide.

9. The semiconductor optical device according to claim 6,
wherein said second layer is made of a material selected from a group of titanium oxide and tantalum oxide.

10. The semiconductor optical device according to claim 6,
wherein said light-generating region further comprise an InP substrate, an n-type InP layer provided on said InP substrate, an active layer provided on said n-type InP layer, and a p-type InP layer provided on said active layer.
